(19) United States
(12) Patent Application Publication
(10) Pub. No.: US 2025/0267907 A1
(43) Pub. Date: Aug. 21, 2025

(54) SEMICONDUCTOR DEVICE AND METHOD OF FORMING THE SAME

(71) Applicant: TAIWAN SEMICONDUCTOR MANUFACTURING COMPANY, LTD., Hsinchu (TW)

(72) Inventors: Wan-Yi KAO, Hsinchu County (TW); Hung Cheng LIN, Hsinchu (TW); Chunyao WANG, Hsinchu County (TW); Tze-Liang LEE, Hsinchu City (TW)

(73) Assignee: TAIWAN SEMICONDUCTOR MANUFACTURING COMPANY, LTD., Hsinchu (TW)

(21) Appl. No.: 18/583,044

(22) Filed: Feb. 21, 2024

(51) Int. Cl. H01L 29/06; H01L 21/027; H01L 21/3105; H01L 21/762; H01L 29/423; H01L 29/66; H01L 29/775; H01L 29/78; H01L 29/786

(52) U.S. Cl. CPC H10D 62/121; H01L 21/0276; H01L 21/31053; H01L 21/76224; H10D 30/014; H10D 30/024; H10D 30/43; H10D 30/62; H10D 30/6735; H10D 30/6757

(57) ABSTRACT

A method comprises the following steps. A substrate is patterned to form a fin protruding from the substrate. The fin has a first portion, a second portion over the first portion, and a third portion over the second portion. Shallow trench isolation (STI) regions are formed over the substrate and surrounding the first portion of the fin. A hard mask structure is formed over the STI regions and surrounding the second portion of the fin. The hard mask structure includes a first dielectric material different from a dielectric material of the STI region. A gate structure is formed on the hard mask structure and across the fin.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2-11, 12A, 19A, 20A, 21A, 22A and 23A illustrate reference cross-section A-A′ illustrated in FIG. 1 of intermediate stages in the manufacturing of nano-FETs, in accordance with some embodiments.

FIGS. 12B, 13B, 14B, 15B, 16B, 17B, 18B, 19B, 20B, 21B, 22B and 23B illustrate reference cross-section B-B′ illustrated in FIG. 1 of intermediate stages in the manufacturing of nano-FETs, in accordance with some embodiments.

FIGS. 12C, 13A, 14A, 15A, 16A, 17A, 18A and 19C illustrate reference cross-section C-C′ illustrated in FIG. 1 of intermediate stages in the manufacturing of nano-FETs, in accordance with some embodiments.

FIGS. 19D, 20C, 21C, 22C, 23C illustrate reference cross-section D-D′ illustrated in FIG. 1 of intermediate stages in the manufacturing of nano-FETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

As the device scales down, maintaining the integrity of shallow trench isolation (STI) regions is increasingly complex. This challenge is particularly evident during certain etching processes, such as those used to pattern a polysilicon layer into dummy gates. These processes, influenced by the high aspect ratios of grooves between dummy gates, often lead to compromised STI regions, which negatively impact both yield and device performance.

The present disclosure provides a hard mask structure for shallow trench isolation (STI) regions. The hard mask structure effectively mitigates the loss of STI regions. Therefore, unwanted merging epitaxial source/drain structures and unwanted deformation to dummy gates (also called poly line collapse) can be prevented, which in turn improves device yield.

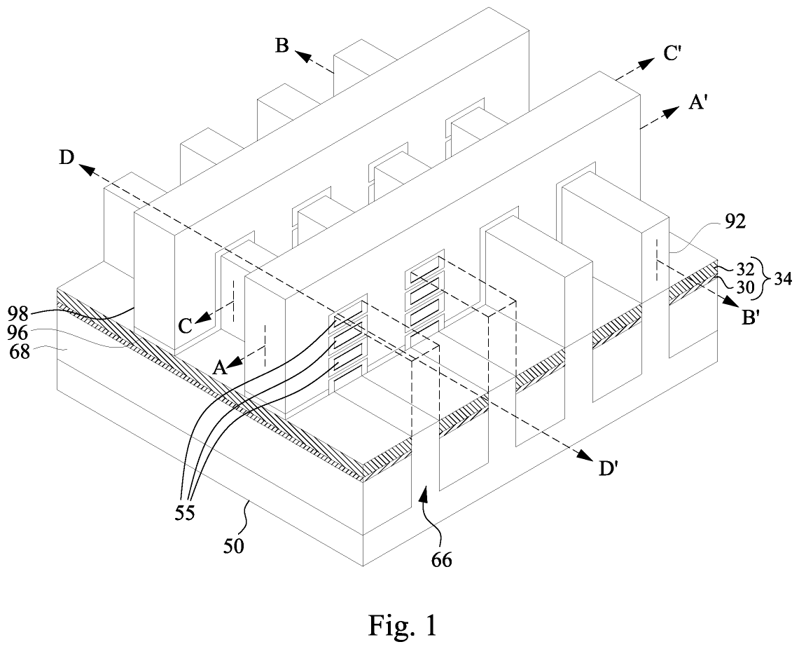

FIG. 1 illustrates an example of nano-FETs (e.g., nanowire FETs, nanosheet FETs, or the like) in a three-dimensional view, in accordance with some embodiments. The nano-FETs comprise nanostructures 55 (e.g., nanosheets, nanowire, or the like) over fins 66 on a substrate 50 (e.g., a semiconductor substrate), wherein the nanostructures 55 act as channel regions for the nano-FETs. The nano-FETs may be gate all around (GAA) transistor structures. The nanostructure 55 may include p-type nanostructures, n-type nanostructures, or a combination thereof. STI regions 68 are disposed between adjacent fins 66, which may protrude above and from between neighboring STI regions 68. Although the STI regions 68 are described/illustrated as being separate from the substrate 50, as used herein, the term “substrate” may refer to the semiconductor substrate alone or a combination of the semiconductor substrate and the isolation regions. Additionally, although a bottom portion of the fins 66 are illustrated as being single, continuous materials with the substrate 50, the bottom portion of the fins 66 and/or the substrate 50 may comprise a single material or a plurality of materials. In this context, the fins 66 refer to the portion extending between the neighboring STI regions 68.

Gate dielectric layers 96 are over top surfaces of the fins 66 and along top surfaces, sidewalls, and bottom surfaces of the nanostructures 55. Gate electrodes 98 are over the gate dielectric layers 96. Epitaxial source/drain regions 92 are disposed on the fins 66 on opposing sides of the gate dielectric layers 96 and the gate electrodes 98.

FIG. 1 further illustrates reference cross-sections that are used in later figures. Cross-section A-A′ is along a longitudinal axis of the gate electrode 98 and in a direction, for example, perpendicular to the direction of current flow between the epitaxial source/drain regions 92 of a nano-FET. Cross-section B-B′ is perpendicular to cross-section A-A′ and is parallel to a longitudinal axis of the fin 66 of the nano-FET and in a direction of, for example, a current flow between the epitaxial source/drain regions 92 of the nano-FET. Cross-section C-C′ is parallel to cross-section A-A′ and extends through epitaxial source/drain regions 92 of the nano-FETs. Cross-section D-D′ is parallel to cross-section B-B′ and extends between adjacent epitaxial source/drain regions 92. Subsequent figures refer to these reference cross-sections for clarity.

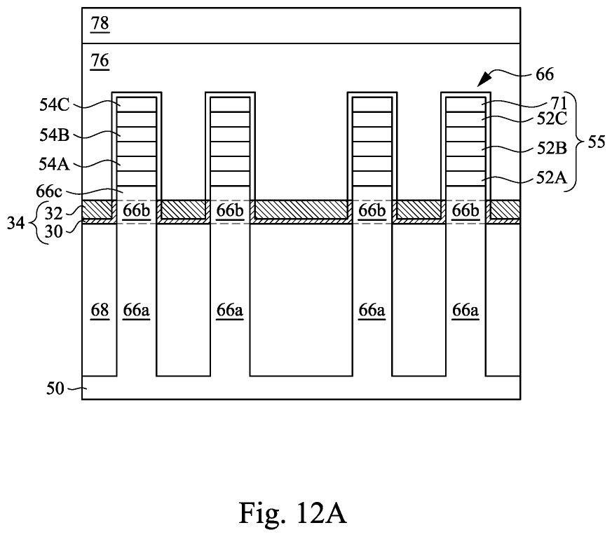

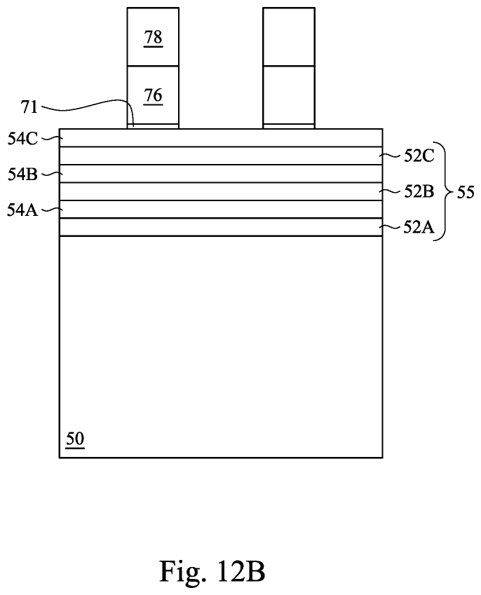

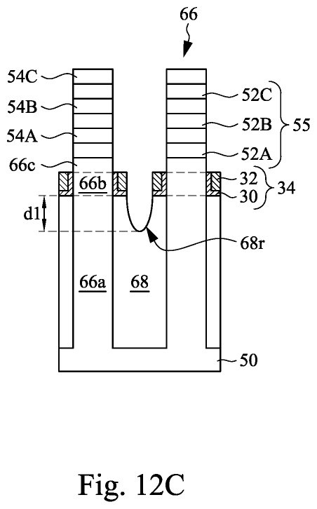

A hard mask structure 34 including a first hard mask layer 30 and a second hard mask layer 32 over the first hard mask layer 30 for protection for the STI regions 68 are formed over the STI regions 68 to mitigate STI regions 68 loss during etching the dummy gates 76 (see FIG. 12A). Therefore, unwanted merging of epitaxial source/drain structures 92 and unwanted deformation to dummy gates (also called poly line collapse, see FIG. 12A) can be prevented, which in turn improves device yield. Also, due to the mitigated loss of STI regions 68, gate to substrate parasitic capacitance can be reduced.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

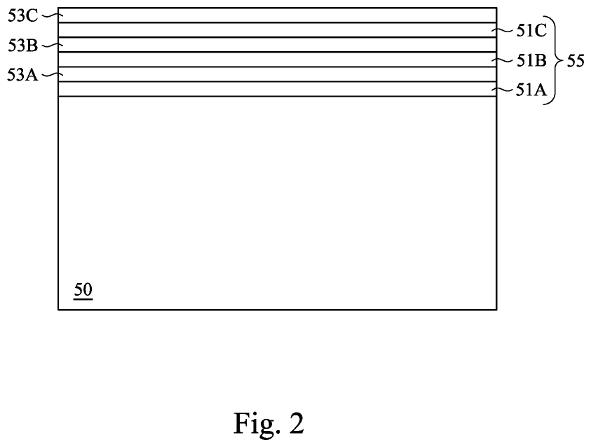

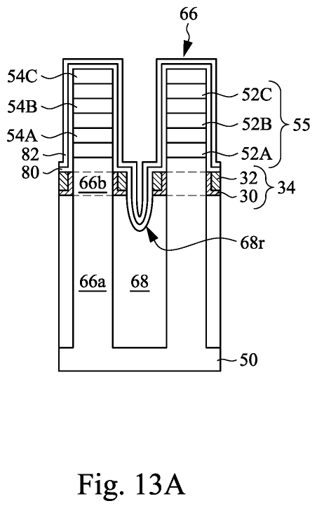

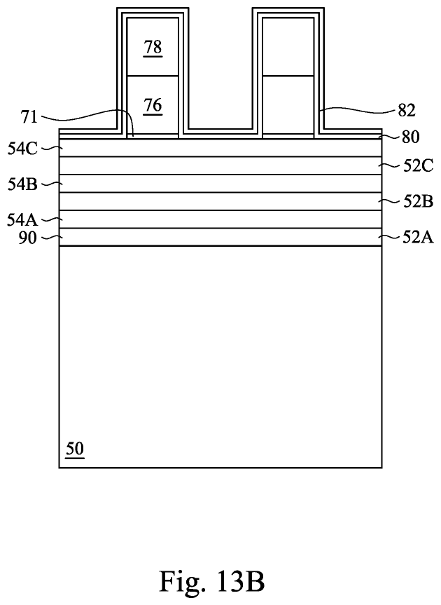

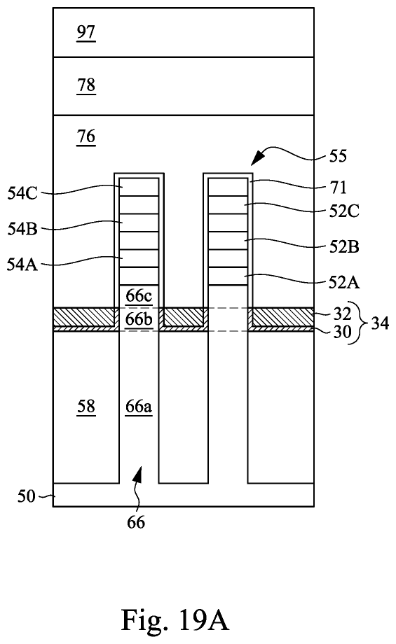

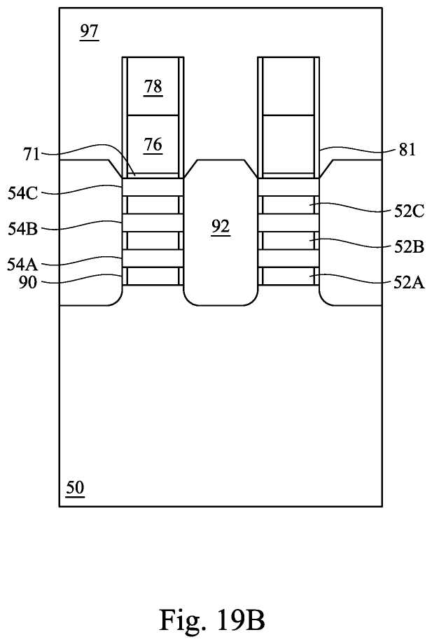

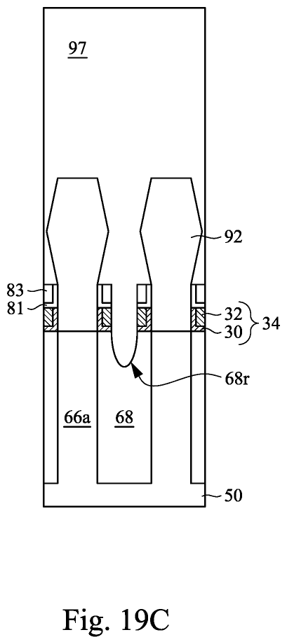

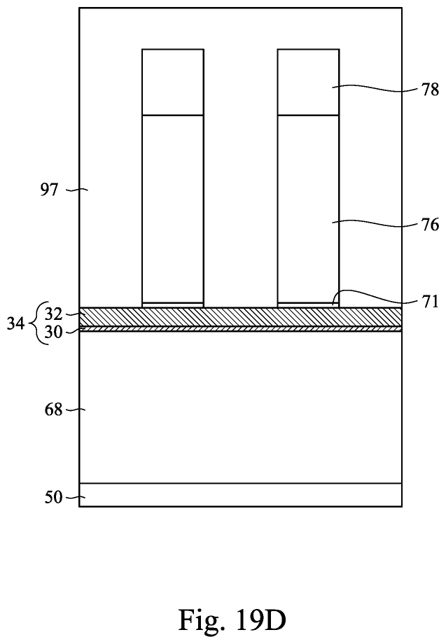

FIGS. 2 through 12B and 13A through 23C are cross-sectional views of intermediate stages in the manufacturing of nano-FETs, in accordance with some embodiments. FIGS. 2-11, 12A, 19A, 20A, 21A, 22A and 23A illustrate reference cross-section A-A′ illustrated in FIG. 1. FIGS. 12B, 13B, 14B, 15B, 16B, 17B, 18B, 19B, 20B, 21B, 22B and 23B illustrate reference cross-section B-B′ illustrated in FIG. 1. FIG. 12C illustrates a three-dimensional view of the nano-FET in accordance with some other embodiments. FIGS. 13A, 14A, 15A, 16A, 17A, 18A and 19C illustrate reference cross-section C-C′ illustrated in FIG. 1. FIGS. 19D, 20C, 21C, 22C, 23C illustrate reference cross-section D-D′ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

Further in FIG. 2, a multi-layer stack 64 is formed over the substrate 50. The multi-layer stack 64 includes alternating layers of first semiconductor layers 51A, 51B, 51C (collectively referred to as first semiconductor layers 51) and second semiconductor layers 53A, 53B, 53C (collectively referred to as second semiconductor layers 53). For purposes of illustration and as discussed in greater detail below, the first semiconductor layers 51 will be removed and the second semiconductor layers 53 will be patterned to form channel regions of the device. Nevertheless, in some embodiments the second semiconductor layers 53 may be removed and the first semiconductor layers 51 may be patterned to form channel regions of the device.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In various embodiments, the first semiconductor layers 51 may be formed of a first semiconductor material suitable for p-type nano-FETs, such as silicon germanium or the like, and the second semiconductor layers 53 may be formed of a second semiconductor material suitable for n-type nano-FETs, such as silicon, silicon carbon, or the like. The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material, thereby allowing the second semiconductor layers 53 to be patterned to form channel regions of NSFETS.

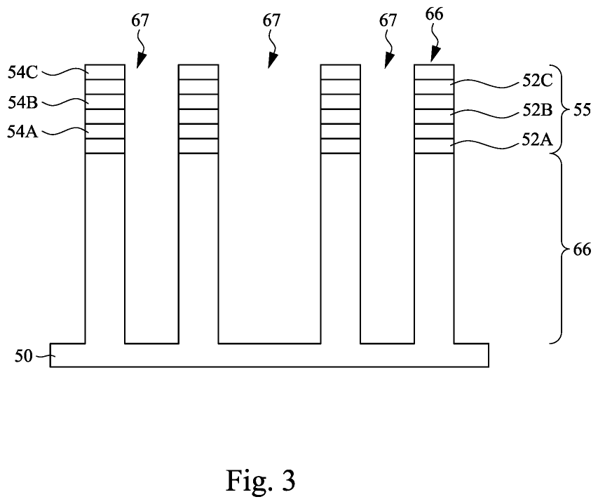

Referring now to FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), neutral beam etch (NBE), the like, or a combination thereof. The etching may be anisotropic. Forming the nanostructures 55 by etching the multi-layer stack 64 may further define first nanostructures 52A, 52B, 52C (collectively referred to as the first nanostructures 52) from the first semiconductor layers 51 and define second nanostructures 54A, 54B, 54C (collectively referred to as the second nanostructures 54) from the second semiconductor layers 53. The first nanostructures 52 and the second nanostructures 54 may further be collectively referred to as nanostructures 55. The fins 66 are separated by trenches 67.

FIG. 3 illustrates the fins 66 and the nanostructures 55 as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

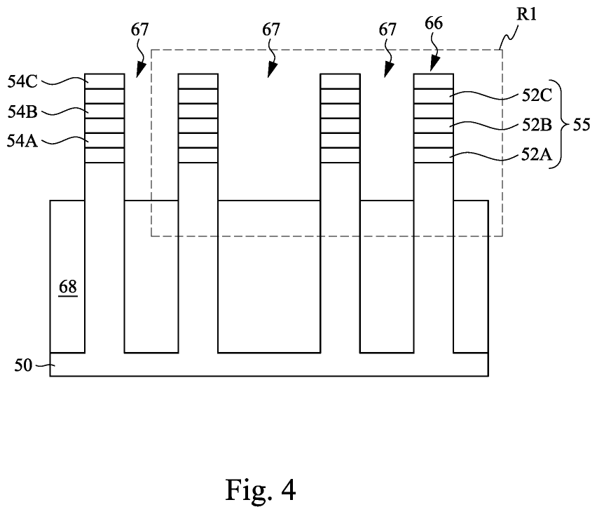

In FIG. 4, shallow trench isolation (STI) regions 68 are formed adjacent the fins 66. In other words, the STI regions 68 may fill in a bottom of the trenches 67. The STI regions 68 may be formed by depositing an insulation material over the substrate 50, the fins 66, and nanostructures 55, and between the adjacent fins 66. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An annealing process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of the fins 66 protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used.

The process described above with respect to FIGS. 2 through 4 is just one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together. Further in FIG. 4, appropriate wells (not separately illustrated) may be formed in the fins 66, the nanostructures 55, and/or the STI regions 68.

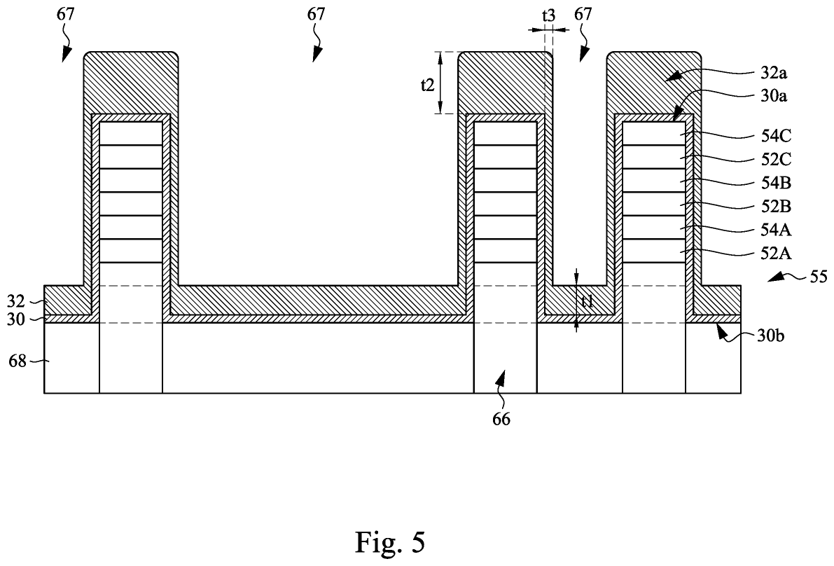

FIGS. 5-9 illustrate cross-sectional views of formation of the hard mask structure 34 (see FIG. 1) in accordance with some embodiments. In FIGS. 5-9, a partial region R1 of the structure in FIG. 4 is illustrated, and for example, the substrate 50 is omitted. In FIG. 5, a first hard mask layer 30 is formed on the fins 66 and/or the nanostructures 55. The first hard mask layer 30 may be, for example, silicon oxide or the like, buried under the second hard mask layer 32, and hence the first hard mask layer 30 is interchangeably referred to as Buried Oxide (BOX) layer. The first hard mask layer may be deposited by physical vapor deposition (PVD), CVD, sputter deposition, or other techniques. The first hard mask layer extends over a top surface of the STI regions 68, along a sidewall of the fins 66, along a sidewall of the nanostructures 55 and over a top surface of the nanostructures 55. In other words, the first hard mask layer 30 has a first portion 30a on a sidewall and a top surface of the fins 66 and a second portion 30b on the STI regions 68. A second hard mask layer 32 is then formed over the first hard mask layer 30. The second hard mask layer 32 may have a top portion 32a over a top surface of the fins 66. In some embodiments, the second hard mask layer 32 and the first hard mask layer 30 include different materials. For example, the second hard mask layer is a nitride layer. In some embodiments, the second hard mask layer 32 may be, for example, silicon nitride or the like. The second hard mask layer 32 may be deposited by physical vapor deposition (PVD), CVD, sputter deposition, or other techniques. The first hard mask layer 30 and the second hard mask layer 32 may be materials having a high-etch selectivity to each other. As such, the first hard mask layer 30 may be removed without significantly removing the second hard mask layer 32 in a subsequent etch process. In some embodiments, the second hard mask layer 32 has different thicknesses at different positions. For example, the second hard mask layer 32 has a first thickness t1 directly over the STI regions 68 in a range from about 10 nm to about 15 nm, such as about 14 nm. In some embodiments, the second hard mask layer 32 has a second thickness t2 directly over the top surface of the nanostructure 55 in a range from about 17 nm to about 23 nm, such as about 20 nm. In some embodiments, the second hard mask layer 32 has a third thickness t3 on a sidewall of the nanostructure 55 in a range from about 1 nm to about 5 nm, such as about 2.6 nm. The thicknesses t1, t2, t3 may be different from one another. For example, the thickness t2 is greater than the thickness t3. The thickness t1 is greater than the thickness t3.

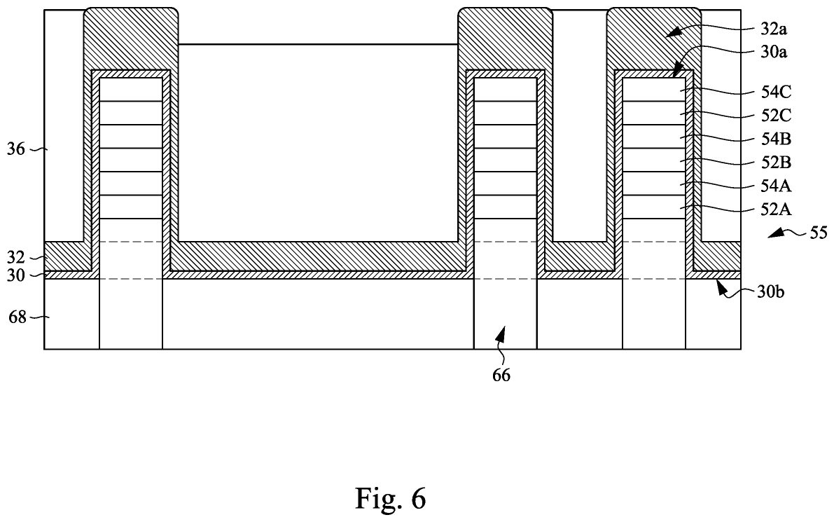

Reference is made to FIG. 6. A bottom anti-reflective coating (BARC) layer 36 is formed on the second hard mask layer 32. The BARC layer 36 is formed adjacent the fins 66, filling into the trenches 67. The BARC layer 36 may be silicon oxynitride. In some other embodiments, the BARC layer 36 may alternatively be a silicon oxycarbide, silicon nitride, tantalum nitride, or any other suitable material. For example, the BARC layer 36 is formed by any of a variety of methods, such as spin coating or chemical vapor deposition (CVD) to cover the second hard mask layer 32, followed by an etch back process, and hence the top surface of the second hard mask layer 32 is exposed. The etch back process may use CF₄ dry etch or buffered hydrofluoric acid (BHF) wet etch to etch silicon dioxide. Other proper process may be utilized to implement the etching back, such as chemical mechanical polishing (CMP). In some embodiments, the BARC layer 36 has an uneven top surface as illustrated in FIG. 6. In particular, the BARC layer 36 is thinner in a pattern-sparse region (i.e., region in which the fins 66 are arranged at a larger pitch) than in a pattern-dense region (i.e., region in which the fins 66 are arranged at a smaller pitch).

After the BARC layer 36 is etched back, a suitable cleaning process, such as standard clean-2 (SC2) followed with a standard clean-1 (SC1) may be performed. The standard clean-2 is, for example, a mixture of deionized (DI) water, hydrochloric (HCl) acid, and hydrogen peroxide (H₂O₂) at a mixture ratio of 5:1:1 of DI:HCl:H₂O₂, and the SC1 is a mixture of DI water, ammonium hydroxide (NH₄OH), and hydrogen peroxide (H₂O₂) at a mixture ratio of 5:1:1 of DI:NH₄OH:H₂O₂. In other embodiments, an isopropyl alcohol (IPA) can be used after the SC1.

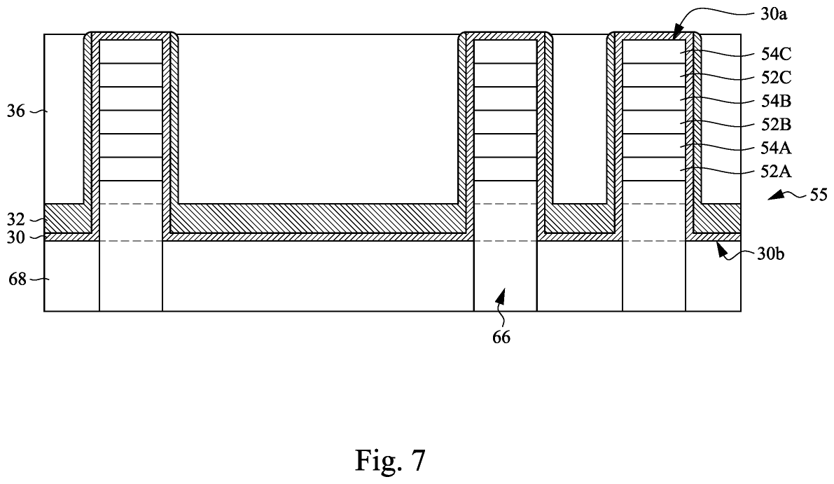

Reference is made to FIG. 7. The second hard mask layer 32 and the BARC layer 36 are trimmed using a suitable trimming process. In some embodiments, the trimming process is an anisotropic plasma etch process with process gases including O₂, CO₂, N₂/H₂, H₂, the like, a combination thereof, or any other gases suitable for trimming the second hard mask layer 32 and the BARC layer 36. The trimming process may be performed to remove the top portion 32a of the second hard mask layer 32 over the top surface of the nanostructures 55 such that the first portion 30a of the first hard mask layer 30 over the top surface of the nanostructures 55 is exposed. After the trimming process, the BARC layer 36 has a flatter top surface than before the trimmer process. For example, the top surface of the BARC layer 36 in the pattern-sparse region (i.e., region in which the fins 66 are arranged at a larger pitch) is substantially level with that in the pattern-dense region (i.e., region in which the fins 66 are arranged at a smaller pitch).

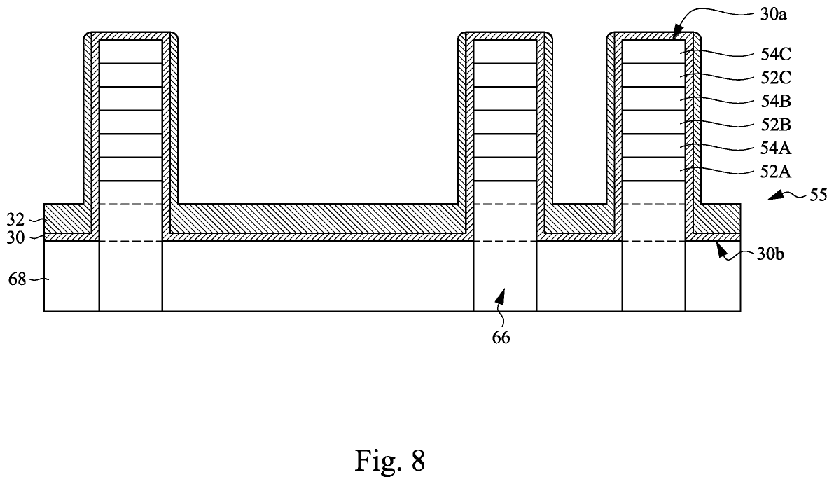

Reference is made to FIG. 8. The BARC layer 36 is removed, exposing the second hard mask layer 32. In some embodiments, the BARC layer 36 may be removed by ashing, reactive ion etching (RIE), ion beam etching (IBE) or the like. After the BARC layer 36 is removed, a suitable cleaning process, such as standard clean-2 (SC2) followed with a standard clean-1 (SC1) may be performed. The cleaning process is similar to the cleaning process as discussed previously with regard to FIG. 6, and thus the description thereof is omitted herein.

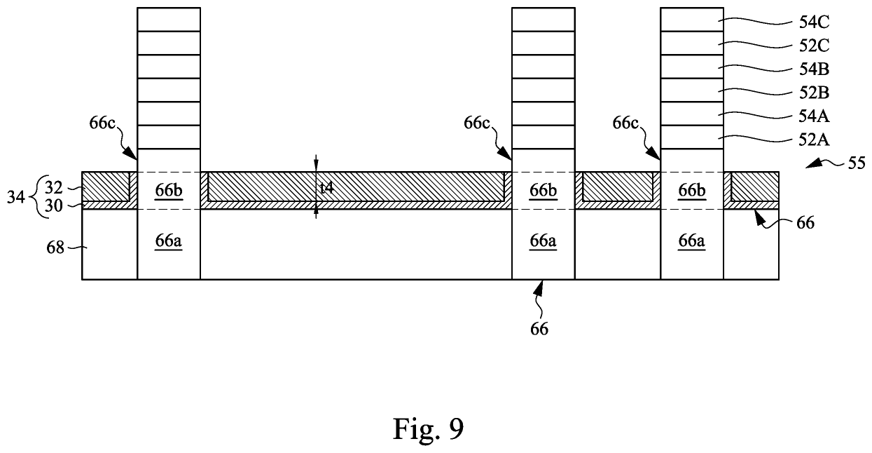

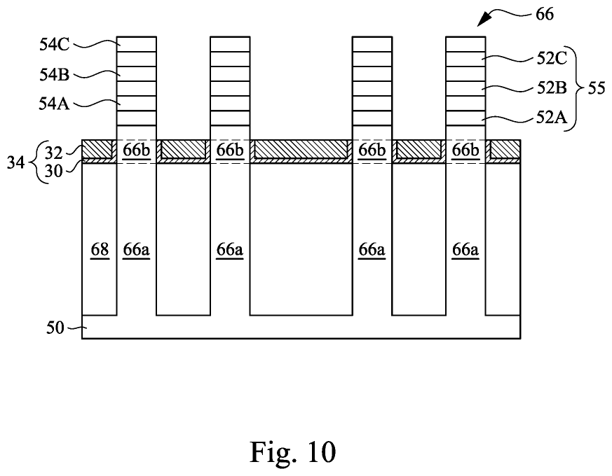

Reference is made to FIGS. 9 and 10. The difference between FIGS. 9 and 10 is that the substrate 50 is omitted in FIG. 9. The second hard mask layer 32 on the sidewalls of the nanostructure 55 is removed. After the second hard mask layer 32 is removed, the first hard mask layer 30 on the sidewalls of the nanostructure 55 is removed, exposing the nanostructures 55. Remaining portions of the first hard mask layer 30 and the second hard mask layer 32 can be collectively referred to as the hard mask structure 34. The fins 66 each have a first portion 66a, a second portion 66b over the first portion 66a and a third portion 66c over the second portion 66b. The hard mask structure 34 surrounds the second portion 66b of the fins 66. The STI regions 68 surround the first portion 66a of the fins 66. The hard mask structure 34 is a multilayer structure and is a dielectric structure. The first hard mask layer 30 includes a dielectric material same as a dielectric material of the STI regions 68. The second hard mask layer 32 includes a dielectric material different from the dielectric material of the STI regions 68. In other words, the hard mask structure 34 includes the dielectric material (i.e., the dielectric material of the second hard mask layer 32) different from the dielectric material of the STI regions 68. In some embodiments, the second hard mask layer 32 and the first hard mask layer 30 on the sidewalls of the nanostructures 55 are removed using a dry (or plasma) process. The first hard mask layer 30 may have a U-shape when viewed from the cross-section. The second hard mask layer 32 may have reduced thickness after removing the second hard mask layer 32 from the sidewall of the nanostructures 55. In some embodiments, the second hard mask layer 32 may have a thickness t4 in a range from about 2 nm to about 8 nm, such as about 5.7 nm. The hard mask structure 34 is configured to protect the underlying STI regions 68, which will be discussed in greater detail below.

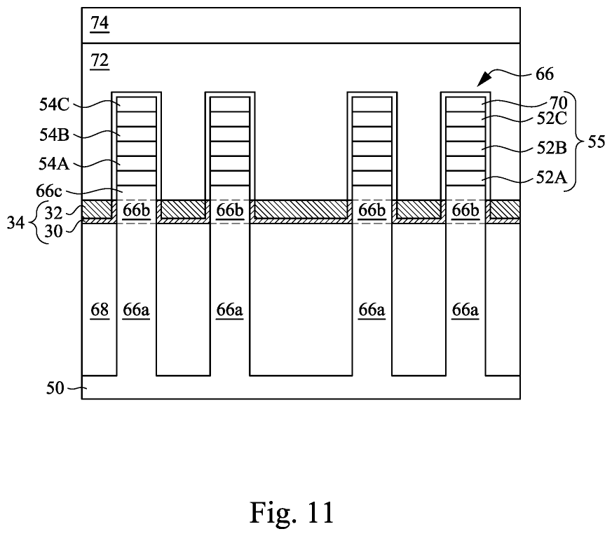

In FIG. 11, a dummy dielectric layer 70 is formed on the fins 66 and/or the nanostructures 55. The dummy dielectric layer 70 is separated from the STI regions 68 by the hard mask structure 34. For example, the dummy dielectric layer 70 may be in contact with the first hard mask layer 30. The dummy dielectric layer 70 may be, for example, silicon oxide, silicon nitride, a combination thereof, or the like, and may be deposited or thermally grown according to acceptable techniques. A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a CMP. The mask layer 74 may be deposited over the dummy gate layer 72. The dummy gate layer 72 is separated from the STI regions 68 by the hard mask structure 34. For example, the dummy gate layer 72 may be in contact with the second hard mask layer 32. The dummy gate layer 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etching selectivity from the etching of isolation regions. The mask layer 74 may include, for example, silicon nitride, silicon oxynitride, or the like. It is noted that the dummy dielectric layer 70 is shown covering only the fins 66 and the nanostructures 55 for illustrative purposes only. In some embodiments, the dummy dielectric layer 70 may be deposited such that the dummy dielectric layer 70 covers the hard mask structure 34, such that the dummy dielectric layer 70 extends between the dummy gate layer 72 and the hard mask structure 34.

In FIGS. 12A and 12B, the mask layer 74 (see FIG. 11) may be patterned using acceptable photolithography and etching techniques to form masks 78. The pattern of the masks 78 then may be transferred to the dummy gate layer 72 and to the dummy dielectric layer 70 to form dummy gates 76 and dummy gate dielectrics 71, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66.

As illustrated in FIG. 12C, due to etching the dummy gates 76, a recess 68r is formed in a top region of the STI regions 68, and the recess 68r extends in depth d1 within the STI regions 68 such that the STI regions 68 have a concave surface. This is also called STI loss. Because the STI regions 68 are protected by the overlying hard mask structure 34, the STI loss amount to the STI regions 68 can be reduced. That is, if the hard mask structure 34 is absent on the STI regions 68, the depth d1 of the recess 68r may be extended deeper in the STI regions 68, which means an increased loss of the STI regions 68. Unwanted deformation to the dummy gates 76 (also called poly line collapse) can be prevented due to the decreased loss of the STI regions 68, which in turn improves the device yield.

In FIGS. 13A and 13B, a first spacer layer 80 and a second spacer layer 82 are formed over the structures illustrated in FIGS. 12A-12C. The first spacer layer 80 and the second spacer layer 82 will be subsequently patterned to act as spacers for forming self-aligned source/drain regions. In FIGS. 13A and 13B, the first spacer layer 80 is formed on top surfaces of the hard mask structure 34; top surfaces and sidewalls of the fins 66, the nanostructures 55, and the masks 78; and sidewalls of the dummy gates 76 and the dummy gate dielectric 71. The first spacer layer 80 extends along the recess 68r. The second spacer layer 82 is deposited over the first spacer layer 80. Portions of the first spacer layer 80 and the second spacer layer 82 are formed in the recess 68r. The first spacer layer 80 may be formed of silicon oxide, silicon nitride, silicon oxynitride, or the like, using techniques such as thermal oxidation or deposited by CVD, ALD, or the like. The second spacer layer 82 may be formed of a material having a different etch rate than the material of the first spacer layer 80, such as silicon oxide, silicon nitride, silicon oxynitride, or the like, and may be deposited by CVD, ALD, or the like.

After the first spacer layer 80 is formed and prior to forming the second spacer layer 82, implants for lightly doped source/drain (LDD) regions (not separately illustrated) may be performed. Appropriate type impurities may be implanted into the exposed fins 66 and nanostructures 55. An annealing may be used to repair implant damage and to activate the implanted impurities.

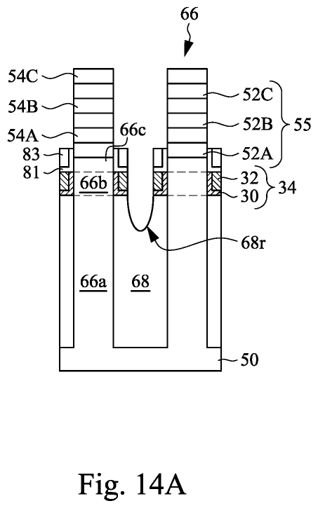

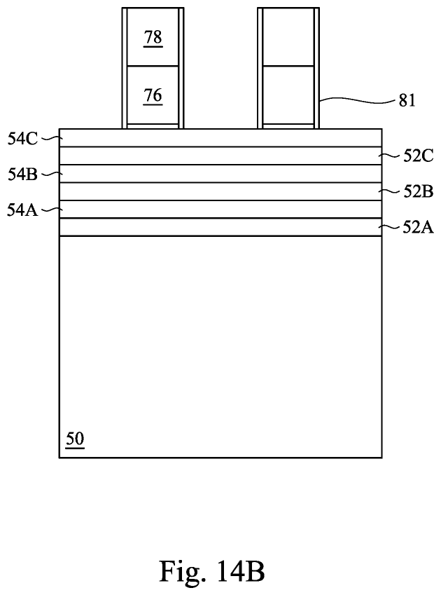

In FIGS. 14A and 14B, the first spacer layer 80 and the second spacer layer 82 are etched to form first spacers 81 and second spacers 83. During etching the first spacer layer 80 and the second spacer layer 82, the portions of the first spacer layer 80 and the second spacer layer 82 formed in the recess 68r may be removed to expose the STI regions 68. As will be discussed in greater detail below, the first spacers 81 and the second spacers 83 act to self-aligned subsequently formed source/drain regions, as well as to protect sidewalls of the fins 66 and/or nanostructure 55 during subsequent processing. The first spacers 81 and the second spacers 83 are at a controlled position due to the mitigated loss of the STI regions 68. For example, the first spacers 81 and the second spacers 83 are supported by the hard mask structure 34 and are at an elevated position due to the hard mask structure 34. The first spacer layer 80 and the second spacer layer 82 may be etched using a suitable etching process, such as an isotropic etching process (e.g., a wet etching process), an anisotropic etching process (e.g., a dry etching process), or the like. In some embodiments, the material of the second spacer layer 82 has a different etch rate than the material of the first spacer layer 80, such that the first spacer layer 80 may act as an etch stop layer when patterning the second spacer layer 82 and such that the second spacer layer 82 may act as a mask when patterning the first spacer layer 80. For example, the second spacer layer 82 may be etched using an anisotropic etch process wherein the first spacer layer 80 acts as an etch stop layer, wherein remaining portions of the second spacer layer 82 form second spacers 83 as illustrated in FIG. 14A. Thereafter, the second spacers 83 acts as a mask while etching exposed portions of the first spacer layer 80, thereby forming first spacers 81 as illustrated in FIG. 14A.

As illustrated in FIG. 14A, the first spacers 81 and the second spacers 83 are disposed on sidewalls of the fins 66 and/or nanostructures 55. As illustrated in FIG. 14B, in some embodiments, the second spacer layer 82 may be removed from over the first spacer layer 80 adjacent the masks 78, the dummy gates 76, and the dummy gate dielectrics 71, and the first spacers 81 are disposed on sidewalls of the masks 78, the dummy gates 76, and the dummy gate dielectrics 60. In other embodiments, a portion of the second spacer layer 82 may remain over the first spacer layer 80 adjacent the masks 78, the dummy gates 76, and the dummy gate dielectrics 71.

It is noted that the above disclosure generally describes a process of forming spacers and LDD regions. Other processes and sequences may be used. For example, fewer or additional spacers may be utilized, different sequence of steps may be utilized (e.g., the first spacers 81 may be patterned prior to depositing the second spacer layer 82), additional spacers may be formed and removed, and/or the like.

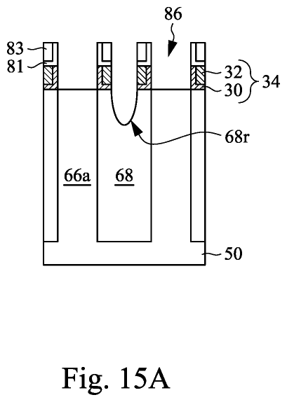

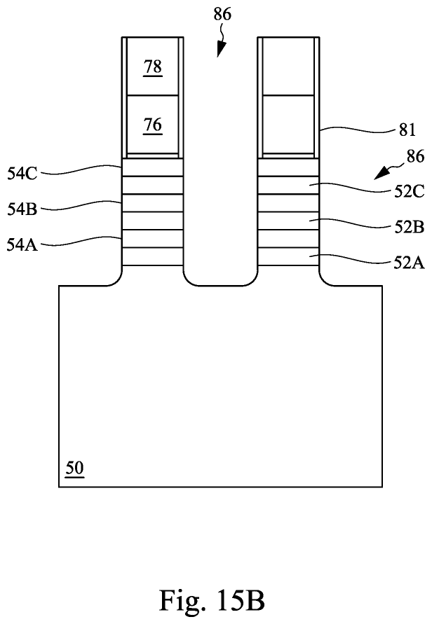

In FIGS. 15A and 15B, first recesses 86 are formed in the fins 66, the nanostructures 55, and the substrate 50, in accordance with some embodiments. Epitaxial source/drain regions will be subsequently formed in the first recesses 86. The first recesses 86 may extend through the first nanostructures 52 and the second nanostructures 54, and into the substrate 50. As illustrated in FIG. 15A, top surfaces of the STI regions 68 may be level with bottom surfaces of the first recesses 86. In various embodiments, the fins 66 may be etched such that bottom surfaces of the first recesses 86 are disposed below the top surfaces of the STI regions 68; or the like. The first recesses 86 may be formed by etching the fins 66, the nanostructures 55, and the substrate 50 using anisotropic etching processes, such as RIE, NBE, or the like. The first spacers 81, the second spacers 83, and the masks 78 mask portions of the fins 66, the nanostructures 55, and the substrate 50 during the etching processes used to form the first recesses 86. A single etch process or multiple etch processes may be used to etch each layer of the nanostructures 55 and/or the fins 66. Timed etch processes may be used to stop the etching of the first recesses 86 after the first recesses 86 reach a desired depth.

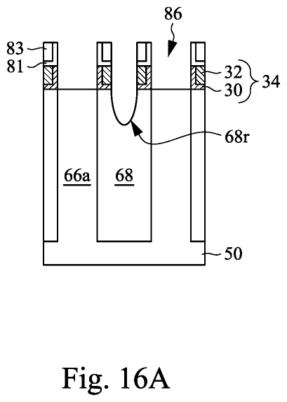

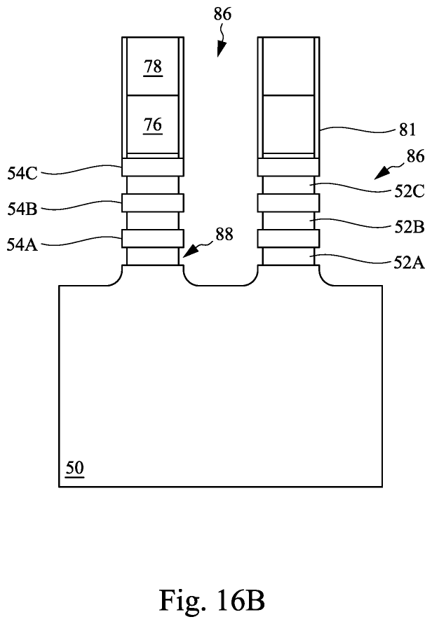

In FIGS. 16A and 16B, portions of sidewalls of the layers of the multi-layer stack 64 formed of the first semiconductor materials (e.g., the first nanostructures 52) exposed by the first recesses 86 are etched to form sidewall recesses 88. Although sidewalls of the first nanostructures 52 in sidewall recesses 88 are illustrated as being straight in FIG. 16B, the sidewalls may be concave or convex. The sidewalls may be etched using isotropic etching processes, such as wet etching or the like. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to etch sidewalls of the first nanostructures 52.

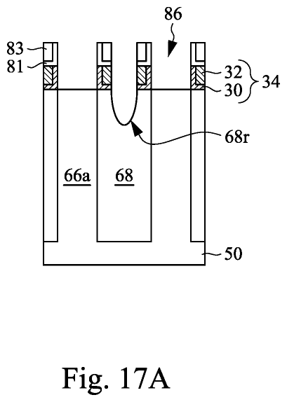

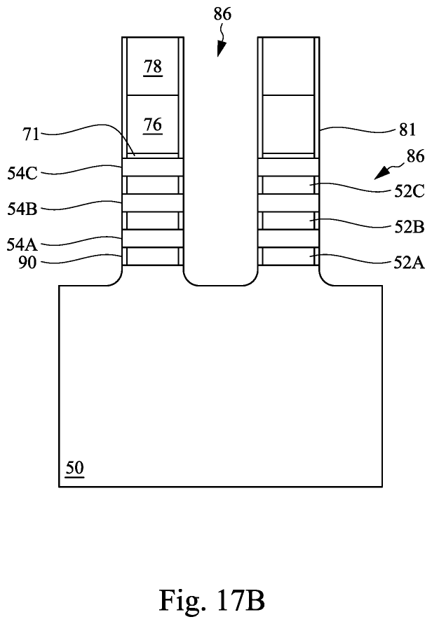

In FIGS. 17A-17B, first inner spacers 90 are formed in the sidewall recess 88. The first inner spacers 90 may be formed by depositing an inner spacer layer (not separately illustrated in FIGS. 17A-17B) over the structures illustrated in FIGS. 16A and 16B. The first inner spacers 90 act as isolation features between subsequently formed source/drain regions and a gate structure. As will be discussed in greater detail below, source/drain regions will be formed in the first recesses 86, while the first nanostructures 52 will be replaced with corresponding gate structures.

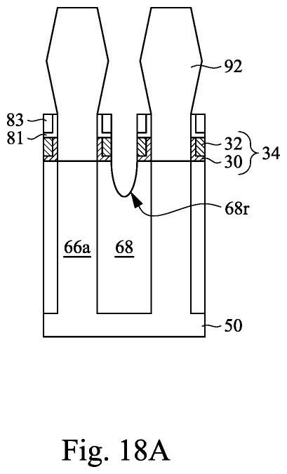

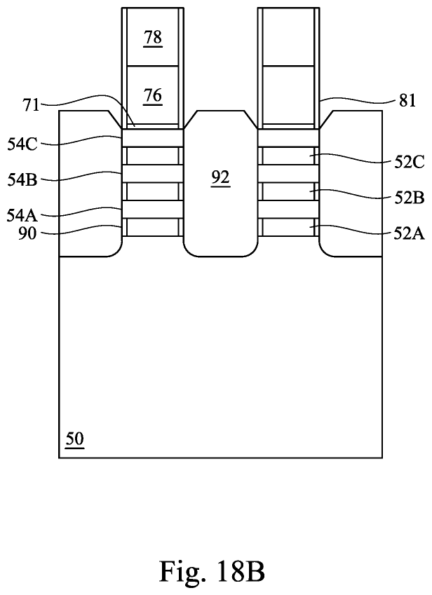

In FIGS. 18A-18B, epitaxial source/drain regions 92 are formed in the first recesses 86. As discussed above, the hard mask structure 34 can allow the first spacers 81 and the second spacers 83 to be at the controlled position due to the mitigated loss of the STI regions 68, and hence merging of the epitaxial source/drain regions 92 caused by the lateral growth of the epitaxial source/drain regions 92 may be prevented. Therefore, the device yield can be improved. In some embodiments, the epitaxial source/drain regions 92 may exert stress on the second nanostructures 54 in, thereby improving performance. As illustrated in FIG. 18B, the epitaxial source/drain regions 92 are formed in the first recesses 86 such that each dummy gate 76 is disposed between respective neighboring pairs of the epitaxial source/drain regions 92. In some embodiments, the first spacers 81 are used to separate the epitaxial source/drain regions 92 from the dummy gate layer 72 and the first inner spacers 90 are used to separate the epitaxial source/drain regions 92 from the nanostructures 55 by an appropriate lateral distance so that the epitaxial source/drain regions 92 do not short out with subsequently formed gates of the resulting nano-FETs.

The epitaxial source/drain regions 92 may include any acceptable material appropriate for n-type nano-FETs or p-type nano-FETs. For example of n-type nano-FETs, if the second nanostructures 54 are silicon, the epitaxial source/drain regions 92 may include materials exerting a tensile strain on the second nanostructures 54, such as silicon, silicon carbide, phosphorous doped silicon carbide, silicon phosphide, or the like. The epitaxial source/drain regions 92 may have surfaces raised from respective upper surfaces of the nanostructures 55 and may have facets.

For example of p-type nano-FETs, the epitaxial source/drain regions 92 may include any acceptable material appropriate for p-type nano-FETs. For example, if the second nanostructures 54 are silicon germanium, the epitaxial source/drain regions 92 may comprise materials exerting a compressive strain on the second nanostructures 54, such as silicon-germanium, boron doped silicon-germanium, germanium, germanium tin, or the like. The epitaxial source/drain regions 92 may also have surfaces raised from respective surfaces of the multi-layer stack 56 and may have facets.

The epitaxial source/drain regions 92, the first nanostructures 52, the second nanostructures 54, and/or the substrate 50 may be implanted with dopants to form source/drain regions, similar to the process previously discussed for forming lightly-doped source/drain regions, followed by an annealing. The n-type and/or p-type impurities for source/drain regions may be any of the impurities previously discussed. In some embodiments, the epitaxial source/drain regions 92 may be in situ doped during growth.

In FIGS. 19A-19D, a first interlayer dielectric (ILD) 97 is deposited over the dummy gates 76, the masks 78, the epitaxial source/drain regions 92 and the hard mask structure 34. The first ILD 97 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. The first ILD 97 is in contact with the hard mask structure 34. In FIG. 19D, the first ILD 97 is separated from the STI regions 68 by the hard mask structure 34.

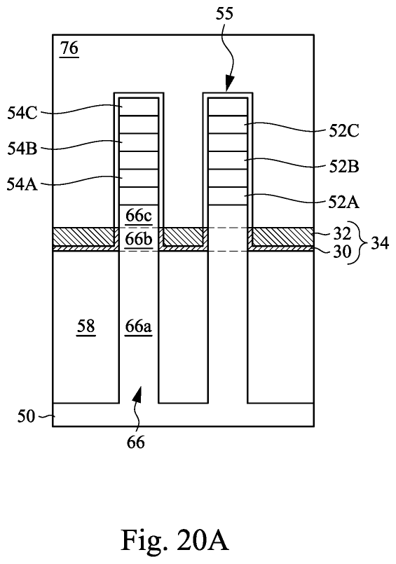

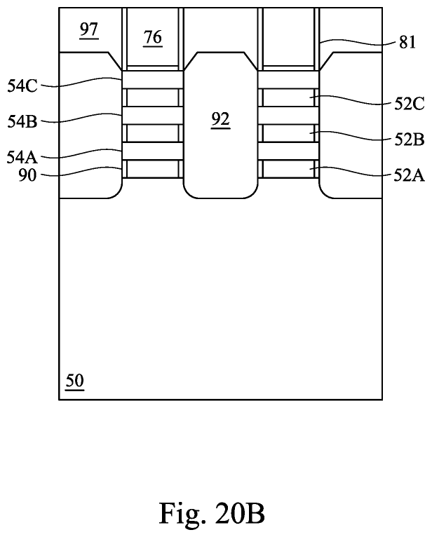

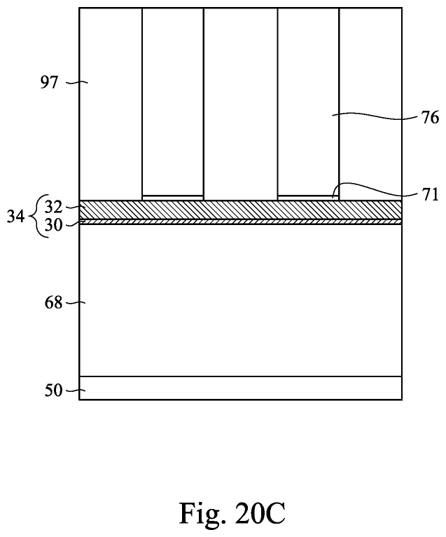

In FIGS. 20A-20B, a planarization process, such as a CMP, may be performed to level the top surface of the first ILD 97 with the top surfaces of the dummy gates 76 or the masks 78. The planarization process may also remove the masks 78 on the dummy gates 76, and portions of the first spacers 81 along sidewalls of the masks 78. After the planarization process, top surfaces of the dummy gates 76, the first spacers 81, and the first ILD 97 are level within process variations. Accordingly, the top surfaces of the dummy gate layer 72 are exposed through the first ILD 97. In some embodiments, the masks 78 may remain, in which case the planarization process levels the top surface of the first ILD 97 with top surface of the masks 78 and the first spacers 81.

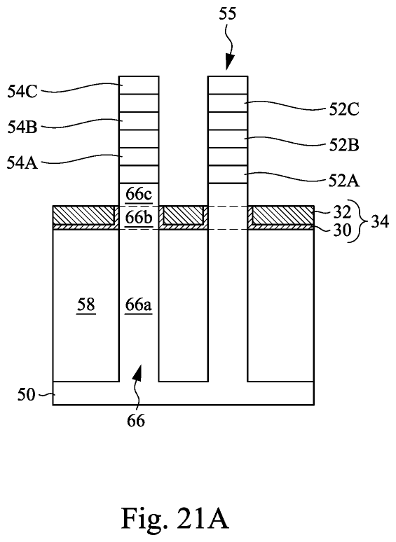

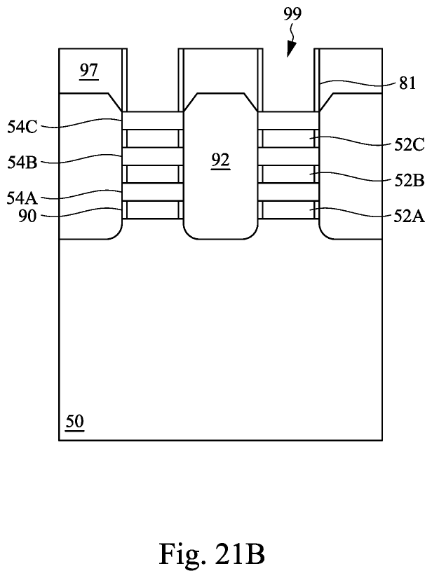

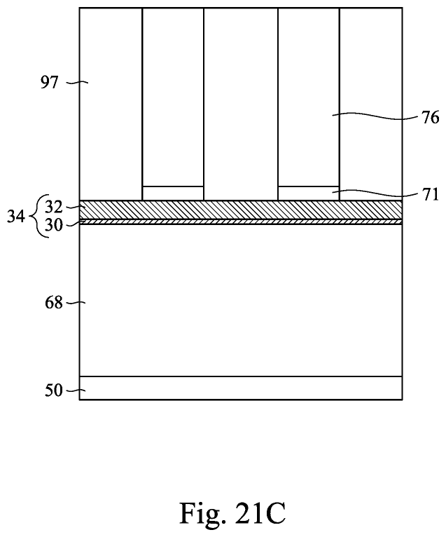

In FIGS. 21A-21C, the dummy gates 76, and the masks 78 if present, are removed in one or more etching steps, so that second recesses 99 are formed. Portions of the dummy gate dielectrics 60 in the second recesses 99 are also be removed. In some embodiments, the dummy gates 76 and the dummy gate dielectrics 71 are removed by an anisotropic dry etch process. For example, the etching process may include a dry etch process using reaction gas(es) that selectively etch the dummy gates 76 at a faster rate than the first ILD 97 or the first spacers 81. Each second recess 99 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy gate dielectrics 71 may be used as etch stop layers when the dummy gates 76 are etched. The dummy gate dielectrics 71 may then be removed after the removal of the dummy gates 76.

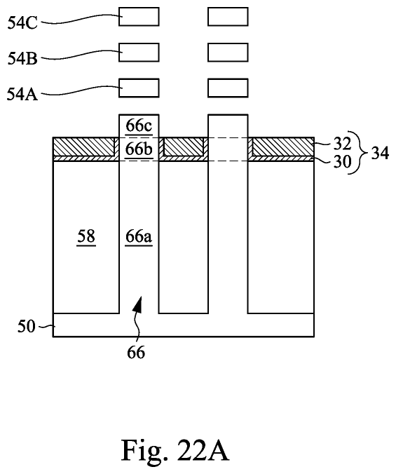

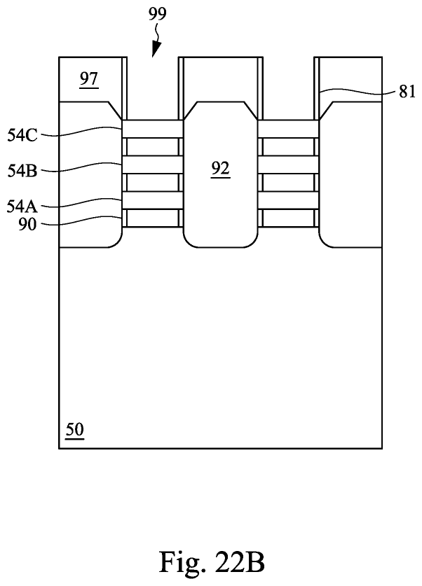

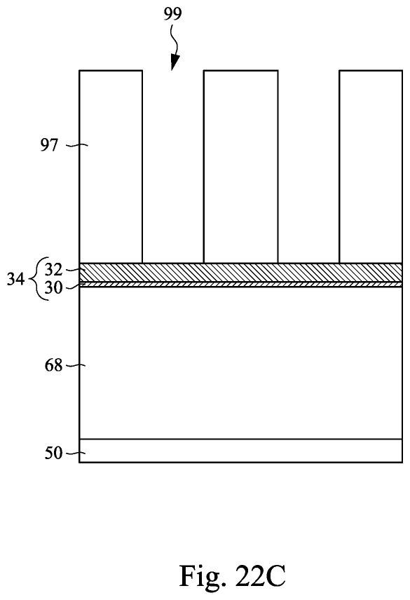

In FIGS. 22A-22C, the first nanostructures 52 are removed extending the second recesses 99. The first nanostructures 52 may be removed an isotropic etching process such as wet etching or the like using etchants which are selective to the materials of the first nanostructures 52, while the second nanostructures 54, the substrate 50, the hard mask structure 34 remain relatively unetched as compared to the first nanostructures 52. In embodiments in which the first nanostructures 52 include, e.g., SiGe, and the second nanostructures 54A-54C include, e.g., Si or SiC, tetramethylammonium hydroxide (TMAH), ammonium hydroxide (NH₄OH), or the like may be used to remove the first nanostructures 52. In embodiments in which the first nanostructures 52 include, e.g., SiGe, and the second nanostructures 54 include, e.g., Si or SiC, hydrogen fluoride, another fluorine-based etchant, or the like may be used to remove the first nanostructures 52. The second nanostructures 54A-54C are over the fins 66 and are arranged in the vertical direction. A topmost position of the hard mask structure 34 is lower than a bottom surface of a bottommost one of the second nanostructures 54A-54C.

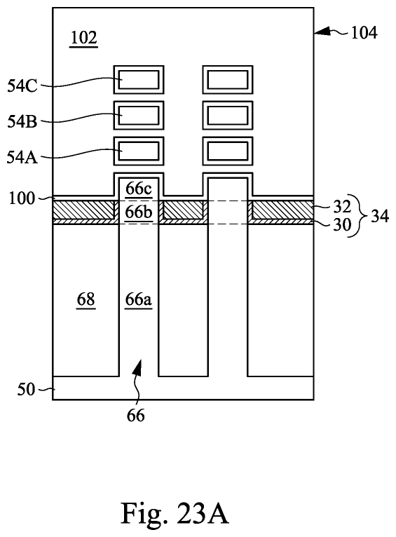

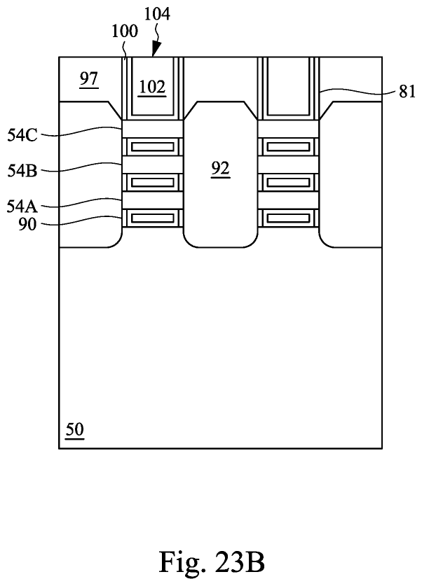

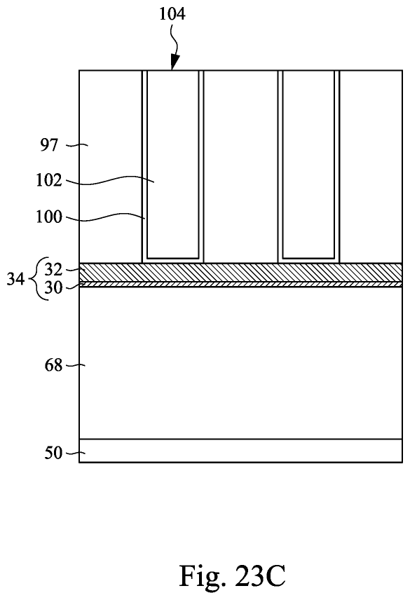

In FIGS. 23A-23C, gate dielectric layers 100 and gate electrodes 102 are formed for replacement gates. The gate dielectric layers 100 are deposited conformally in the second recesses 99. The gate dielectric layers 100 may be formed on top surfaces and sidewalls of the substrate 50 and on top surfaces, sidewalls, and bottom surfaces of the second nanostructures 54. The gate dielectric layers 100 may also be deposited on top surfaces of the first ILD 97, the first spacers 81, and on a top surface of the hard mask structure 34.

In accordance with some embodiments, the gate dielectric layers 100 comprise one or more dielectric layers, such as an oxide, a metal oxide, the like, or combinations thereof. For example, in some embodiments, the gate dielectric layers 100 may comprise a silicon oxide layer and a metal oxide layer over the silicon oxide layer. In some embodiments, the gate dielectric layers 100 include a high-k dielectric material, and in these embodiments, the gate dielectric layers 100 may have a k value greater than about 7.0, and may include a metal oxide or a silicate of hafnium, aluminum, zirconium, lanthanum, manganese, barium, titanium, lead, and combinations thereof. The formation methods of the gate dielectric layers 100 may include molecular-beam deposition (MBD), ALD, PECVD, and the like.

The gate electrodes 102 are deposited over the gate dielectric layers 100, respectively, and fill the remaining portions of the second recesses 99. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 23A and 23B, the gate electrodes 102 may comprise any number of liner layers, any number of work function tuning layers, and a fill material.

After the filling of the second recesses 99, a planarization process, such as a CMP, may be performed to remove the excess portions of the gate dielectric layers 100 and the material of the gate electrodes 102, which excess portions are over the top surface of the first ILD 97. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures 104.”

Embodiments may achieve advantages. For example, in embodiments in which the hard mask structure is formed on the STI regions, the hard mask structure can effectively mitigate loss of STI regions during etching the dummy gates. The hard mask structure can allow the first spacers and the second spacers to be at the controlled position, and hence merging of the epitaxial source/drain regions caused by the lateral growth of the epitaxial source/drain regions may be prevented. Also, due to the mitigated loss of STI regions, gate to substrate parasitic capacitance can be reduced.

In some embodiments, a method comprises the following steps. A substrate is patterned to form a fin protruding from the substrate, wherein the fin has a first portion, a second portion over the first portion, and a third portion over the second portion. Shallow trench isolation (STI) regions are formed over the substrate and surrounding the first portion of the fin. A hard mask structure is formed over the STI regions and surrounding the second portion of the fin, wherein the hard mask structure includes a first dielectric material different from a dielectric material of the STI region. A gate structure is formed on the hard mask structure and across the fin. In some embodiments, forming the hard mask structure comprises forming a first hard mask layer of a second dielectric material over the fin and forming a second hard mask layer of the first dielectric material over the first hard mask layer, wherein the second dielectric material is different from the first dielectric material. In some embodiments, the second dielectric material comprises silicon oxide, and the first dielectric material comprises silicon nitride. In some embodiments, the first hard mask layer has a U-shape when viewed from a cross-sectional view. In some embodiments, the method further comprises forming an inter-layer dielectric (ILD) layer on the hard mask structure and the gate structure, wherein the hard mask structure is in contact with the ILD layer. In some embodiments, forming the hard mask structure comprises the following steps. A first hard mask layer is formed having a first portion on a sidewall and a top surface of the fin and a second portion on the STI regions. A second hard mask layer is formed over the first hard mask layer, wherein the second hard mask layer has a top portion over the top surface of the fin. A bottom anti-reflective coating (BARC) layer is formed over the second hard mask layer. The top portion of the second hard mask layer is removed over the top surface of the fin. The BARC layer is removed. In some embodiments, forming the hard mask structure further comprises after removing the BARC layer, etching the first portion of the first hard mask layer.

In some embodiments, a method comprises the following steps. Fins are formed on a substrate, wherein each of the fins comprises alternately stacked first semiconductor structures and second semiconductor structures. Shallow trench isolation (STI) regions are formed between the adjacent fins. A first hard mask layer is formed over the STI regions. A second hard mask layer is formed over the first hard mask layer. A bottom anti-reflective coating (BARC) layer is deposited on the second hard mask layer. A planarization process is performed to planarize the BARC layer and the second hard mask layer. The BARC layer is removed. The first semiconductor structures are removed to form spaces each between the second semiconductor structures. A gate structure is formed wrapping the second semiconductor structures. In some embodiments, prior to removing the BARC layer, the first hard mask layer is present over a top surface of each of the fins. In some embodiments, the STI regions is in contact with the first hard mask layer. In some embodiments, the first hard mask layer and the second hard mask layer include different materials. In some embodiments, the second hard mask layer and the STI regions include different materials. In some embodiments, the method further comprises prior to removing the first semiconductor structures, forming an interlayer dielectric (ILD) layer on the second hard mask layer, wherein the second hard mask layer is vertically between the ILD layer and the STI regions. In some embodiments, the second hard mask layer is vertically between the STI regions and the gate structure. In some embodiments, the method further comprises after removing the BARC layer, etching the first hard mask layer and the second hard mask layer such that the fins have a sidewall uncovered by the first hard mask layer and the second hard mask layer.

In some embodiments, a semiconductor device comprises a fin, a plurality of nanostructures, shallow trench isolation (STI) regions, a gate structure and an interlayer dielectric (ILD) layer. The fin protrudes from a substrate. The plurality of nanostructures is over the fin and arranged in a vertical direction. The shallow trench isolation (STI) regions surround the fin. The hard mask structure is on the STI regions. The gate structure wraps around the plurality of nanostructures and on the hard mask structure. The ILD layer surrounds the gate structure and is over the hard mask structure. In some embodiments, the hard mask structure is a multilayer structure. In some embodiments, a topmost position of the hard mask structure is lower than a bottom surface of a bottommost one of the plurality of nanostructures. In some embodiments, the hard mask structure comprises a first hard mask layer and a second hard mask layer over the first hard mask layer, wherein the second hard mask layer has a material different from a material of the first hard mask layer. In some embodiments, the second hard mask layer is a nitride layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
patterning a substrate to form a fin protruding from the substrate, wherein the fin has a first portion, a second portion over the first portion, and a third portion over the second portion;
forming shallow trench isolation (STI) regions over the substrate and surrounding the first portion of the fin;
forming a hard mask structure over the STI regions and surrounding the second portion of the fin, wherein the hard mask structure includes a first dielectric material different from a dielectric material of the STI region; and
forming a gate structure on the hard mask structure and across the fin.

2. The method of claim 1, wherein forming the hard mask structure comprises:
forming a first hard mask layer of a second dielectric material over the fin; and
forming a second hard mask layer of the first dielectric material over the first hard mask layer, wherein the second dielectric material is different from the first dielectric material.

3. The method of claim 2, wherein the second dielectric material comprises silicon oxide, and the first dielectric material comprises silicon nitride.

4. The method of claim 2, wherein the first hard mask layer has a U-shape when viewed from a cross-sectional view.

5. The method of claim 1, further comprising:
forming an inter-layer dielectric (ILD) layer on the hard mask structure and the gate structure, wherein the hard mask structure is in contact with the ILD layer.

6. The method of claim 1, wherein forming the hard mask structure comprises:
forming a first hard mask layer having a first portion on a sidewall and a top surface of the fin and a second portion on the STI regions;
forming a second hard mask layer over the first hard mask layer, wherein the second hard mask layer has a top portion over the top surface of the fin;
forming a bottom anti-reflective coating (BARC) layer over the second hard mask layer;
removing the top portion of the second hard mask layer over the top surface of the fin; and
removing the BARC layer.

7. The method of claim 6, wherein forming the hard mask structure further comprises:
after removing the BARC layer, etching the first portion of the first hard mask layer.

8. A method, comprising:
forming fins on a substrate, wherein each of the fins comprises alternately stacked first semiconductor structures and second semiconductor structures;
forming shallow trench isolation (STI) regions between the adjacent fins;
forming a first hard mask layer over the STI regions;
forming a second hard mask layer over the first hard mask layer;
depositing a bottom anti-reflective coating (BARC) layer on the second hard mask layer;
performing a planarization process to planarize the BARC layer and the second hard mask layer;
removing the BARC layer;
removing the first semiconductor structures to form spaces each between the second semiconductor structures; and
forming a gate structure wrapping the second semiconductor structures.

9. The method of claim 8, wherein prior to removing the BARC layer, the first hard mask layer is present over a top surface of each of the fins.

10. The method of claim 8, wherein the STI regions is in contact with the first hard mask layer.

11. The method of claim 8, wherein the first hard mask layer and the second hard mask layer include different materials.

12. The method of claim 8, wherein the second hard mask layer and the STI regions include different materials.

13. The method of claim 8, further comprising:
prior to removing the first semiconductor structures, forming an interlayer dielectric (ILD) layer on the second hard mask layer, wherein the second hard mask layer is vertically between the ILD layer and the STI regions.

14. The method of claim 8, wherein the second hard mask layer is vertically between the STI regions and the gate structure.

15. The method of claim 8, further comprising:
after removing the BARC layer, etching the first hard mask layer and the second hard mask layer such that the fins have a sidewall uncovered by the first hard mask layer and the second hard mask layer.

16. A semiconductor device, comprising:
a fin protruding from a substrate;
a plurality of nanostructures over the fin and arranged in a vertical direction;
shallow trench isolation (STI) regions surrounding the fin;
a hard mask structure on the STI regions;
a gate structure wrapping around the plurality of nanostructures and on the hard mask structure; and
an interlayer dielectric (ILD) layer surrounding the gate structure and over the hard mask structure.

17. The semiconductor device of claim 16, wherein the hard mask structure is a multilayer structure.

18. The semiconductor device of claim 16, wherein a topmost position of the hard mask structure is lower than a bottom surface of a bottommost one of the plurality of nanostructures.

19. The semiconductor device of claim 16, wherein the hard mask structure comprises:
a first hard mask layer; and
a second hard mask layer over the first hard mask layer, wherein the second hard mask layer has a material different from a material of the first hard mask layer.

20. The semiconductor device of claim 19, wherein the second hard mask layer is a nitride layer.
